(19) United States
(12) Patent Application Publication
(10) Pub. No.: US 2025/0264566 A1
(43) Pub. Date: Aug. 21, 2025

(54) MAGNETIC RESONANCE IMAGING APPARATUS AND CONTROL METHOD THEREOF

(71) Applicant: FUJIFILM Corporation, Tokyo (JP)

(72) Inventor: Takashi NISHIHARA, Tokyo (JP)

(73) Assignee: FUJIFILM Corporation, Tokyo (JP)

(21) Appl. No.: 19/051,180

(22) Filed: Feb. 12, 2025

(30) Foreign Application Priority Data
Feb. 16, 2024 (JP) 2024-021849

(51) Int. Cl. G01R 33/565; G01R 33/56

(52) U.S. Cl. CPC G01R 33/56563; G01R 33/5608

(57) ABSTRACT

Provided is a magnetic resonance imaging apparatus that shortens a duration of confinement for a subject during acquisition of data for static magnetic field correction. The magnetic resonance imaging apparatus acquires an imaging site of a subject, sets a first phase encoding number corresponding to the acquired imaging site, controls operations of a transmission device, a reception device, and a gradient magnetic field generating device to acquire a first nuclear magnetic resonance signal with the first phase encoding number, controls the operations of the transmission device, the reception device, and the gradient magnetic field generating device and controls a compensation magnetic field generating device based on the first nuclear magnetic resonance signal to acquire a second nuclear magnetic resonance signal with a second phase encoding number greater than the first phase encoding number, and reconstructs an image of the subject based on the second nuclear magnetic resonance signal.

### CROSS-REFERENCE TO RELATED APPLICATION

The present application claims priority under 35 U.S.C § 119(a) to Japanese Patent Application No. 2024-021849 filed on Feb. 16, 2024, which is hereby expressly incorporated by reference, in its entirety, into the present application.

### BACKGROUND OF THE INVENTION

### 1. Field of the Invention

The present invention relates to a magnetic resonance imaging apparatus and a control method thereof, and particularly, to a technique of correcting a static magnetic field.

### 2. Description of the Related Art

The magnetic resonance imaging apparatus applies a high-frequency magnetic field to a subject placed in a uniform static magnetic field to induce a nuclear magnetic resonance phenomenon in atomic nuclei (protons) present in any region of the subject, and obtains a tomographic image of the region from a nuclear magnetic resonance signal generated by the nuclear magnetic resonance phenomenon. In this case, a gradient magnetic field is applied together with the high-frequency magnetic field in order to selectively excite a specific region, and an applied magnetic field and strength of the gradient magnetic field are controlled in order to impart spatial position information to a nuclear magnetic resonance signal to be measured.

In a case in which a gradient magnetic field is applied in the magnetic resonance imaging apparatus, static magnetic field inhomogeneity such as Z², XY, ZY, or XZ occurs depending on an application axis and an application strength of the gradient magnetic field, which causes image quality degradation. Therefore, various means for correcting the static magnetic field inhomogeneity caused by Maxwell terms have been studied.

For example, JP2002-85376A discloses a technique of acquiring correction data necessary for correcting static magnetic field inhomogeneity before imaging.

### SUMMARY OF THE INVENTION

The data necessary for correcting the static magnetic field inhomogeneity is acquired by imaging at least an imaging target site of the subject, in the same manner as in main imaging. However, in a case of high-resolution imaging, there is a problem in that a time required to acquire data for correction, which is not used for diagnosis, increases, leading to a longer duration of confinement for the subject.

The present invention has been made in view of such circumstances, and an object of the present invention is to provide a magnetic resonance imaging apparatus that shortens a duration of confinement for a subject during acquisition of data for static magnetic field correction, and a control method thereof.

In order to achieve the above-described object, according to a first aspect of the present disclosure, there is provided a magnetic resonance imaging apparatus comprising: a static magnetic field generating device that generates a static magnetic field; a transmission device that irradiates a subject placed in a static magnetic field space with a high-frequency magnetic field pulse; a reception device that receives a nuclear magnetic resonance signal generated from the subject by the irradiation of the high-frequency magnetic field pulse; a gradient magnetic field generating device that generates a gradient magnetic field in the static magnetic field space; a compensation magnetic field generating device that corrects inhomogeneity of the static magnetic field; and at least one processor, in which the processor is configured to: acquire an imaging site of the subject; set a first phase encoding number corresponding to the acquired imaging site; control operations of the transmission device, the reception device, and the gradient magnetic field generating device to acquire a first nuclear magnetic resonance signal with the first phase encoding number; control the operations of the transmission device, the reception device, and the gradient magnetic field generating device and control the compensation magnetic field generating device based on the first nuclear magnetic resonance signal to acquire a second nuclear magnetic resonance signal with a second phase encoding number greater than the first phase encoding number; and reconstruct an image of the subject based on the second nuclear magnetic resonance signal.

According to the present aspect, since the first nuclear magnetic resonance signal for static magnetic field correction is acquired with the first phase encoding number smaller than the second phase encoding number during main imaging, a required amount of data acquisition for static magnetic field correction is minimized, and the duration of confinement for the subject can be shortened.

According to a second aspect of the present disclosure, in the magnetic resonance imaging apparatus according to the first aspect, it is preferable that the processor is configured to: acquire an imaging protocol; and acquire the first nuclear magnetic resonance signal in a case in which the acquired imaging protocol requires correction of the static magnetic field.

According to a third aspect of the present disclosure, in the magnetic resonance imaging apparatus according to the first or second aspect, it is preferable that a table in which the imaging site of the subject and the first phase encoding number are stored in association with each other is provided, and the processor is configured to set the first phase encoding number by referring to the table.

According to a fourth aspect of the present disclosure, in the magnetic resonance imaging apparatus according to any one of the first to third aspects, it is preferable that the processor is configured to: acquire subject information including at least one of an age, a sex, or a body type; and set the first phase encoding number according to the acquired information.

According to a fifth aspect of the present disclosure, in the magnetic resonance imaging apparatus according to any one of the first to fourth aspects, it is preferable that the processor is configured to: acquire a size of the imaging site of the subject; and set the first phase encoding number according to the acquired size.

According to a sixth aspect of the present disclosure, in the magnetic resonance imaging apparatus according to the fifth aspect, it is preferable that the processor is configured to: acquire a captured image of the subject; and acquire a size of the imaging site from the acquired captured image.

According to a seventh aspect of the present disclosure, in the magnetic resonance imaging apparatus according to the sixth aspect, it is preferable that the processor is configured to: acquire a captured image of an entire body of the subject; and acquire the size of the imaging site from a ratio of the imaging site to the entire body.

According to an eighth aspect of the present disclosure, in the magnetic resonance imaging apparatus according to any one of the first to seventh aspects, it is preferable that the processor is configured to: acquire a captured image of an entire body of the subject; display the captured image of the entire body on a display device; and acquire a site selected by a user from the displayed captured image of the entire body as the imaging site.

According to a ninth aspect of the present disclosure, in the magnetic resonance imaging apparatus according to any one of the first to eighth aspects, it is preferable that the processor is configured to: acquire a captured image of an entire body of the subject; acquire a plurality of the imaging sites from the acquired captured image of the entire body; and set the first phase encoding number for each of the acquired plurality of imaging sites.

According to a tenth aspect of the present disclosure, in the magnetic resonance imaging apparatus according to any one of the first to ninth aspects, it is preferable that the processor is configured to set the first phase encoding number according to resolution set for each imaging site.

According to an eleventh aspect of the present disclosure, in the magnetic resonance imaging apparatus according to any one of the first to tenth aspects, it is preferable that the processor is configured to set the first phase encoding number according to magnetic field distortion set for each imaging site.

According to a twelfth aspect of the present disclosure, in the magnetic resonance imaging apparatus according to any one of the first to eleventh aspects, it is preferable that the processor is configured to: acquire a period of body motion of the acquired imaging site; and set the first phase encoding number such that acquisition of the first nuclear magnetic resonance signal is completed within the acquired period.

In order to achieve the above-described object, according to a thirteenth aspect of the present disclosure, there is provided a control method of a magnetic resonance imaging apparatus including a static magnetic field generating device that generates a static magnetic field, a transmission device that irradiates a subject placed in a static magnetic field space with a high-frequency magnetic field pulse, a reception device that receives a nuclear magnetic resonance signal generated from the subject by the irradiation of the high-frequency magnetic field pulse, a gradient magnetic field generating device that generates a gradient magnetic field in the static magnetic field space, and a compensation magnetic field generating device that corrects inhomogeneity of the static magnetic field, the control method comprising: acquiring an imaging site of the subject; setting a first phase encoding number corresponding to the acquired imaging site; controlling operations of the transmission device, the reception device, and the gradient magnetic field generating device to acquire a first nuclear magnetic resonance signal with the first phase encoding number; controlling the operations of the transmission device, the reception device, and the gradient magnetic field generating device and controlling the compensation magnetic field generating device based on the first nuclear magnetic resonance signal to acquire a second nuclear magnetic resonance signal with a second phase encoding number greater than the first phase encoding number; and reconstructing an image of the subject based on the second nuclear magnetic resonance signal.

According to the present aspect, since the data for static magnetic field correction is acquired with the first phase encoding number smaller than the second phase encoding number during the main imaging, a required amount of data for static magnetic field correction is minimized, and the duration of confinement for the subject during the acquisition of the data for static magnetic field correction can be shortened.

According to the present invention, it is possible to shorten the duration of confinement for the subject during the acquisition of the data for static magnetic field correction.

### BRIEF DESCRIPTION OF THE DRAWINGS

FIG. 1 is a block diagram showing an overall configuration of an embodiment of a magnetic resonance imaging apparatus.

FIG. 2 is a flowchart showing steps of an imaging method.

FIG. 3 is a diagram showing an example of a table.

FIG. 4 is a diagram illustrating acquisition of a size of an imaging site of a subject.

FIG. 5 is a diagram showing a table in which a size category of the imaging site and Np correspond to each other.

FIG. 6 is a diagram showing an example of a table for obtaining the size of the imaging site of the subject.

FIG. 7 is a diagram showing an example of a multi-echo gradient echo sequence.

### DESCRIPTION OF THE PREFERRED EMBODIMENTS

Hereinafter, preferred embodiments of a magnetic resonance imaging apparatus and a control method thereof according to the present disclosure will be described with reference to the accompanying drawings. In the present specification, the same reference numerals are assigned to the same components, and duplicate descriptions are omitted as appropriate.

### MRI Apparatus

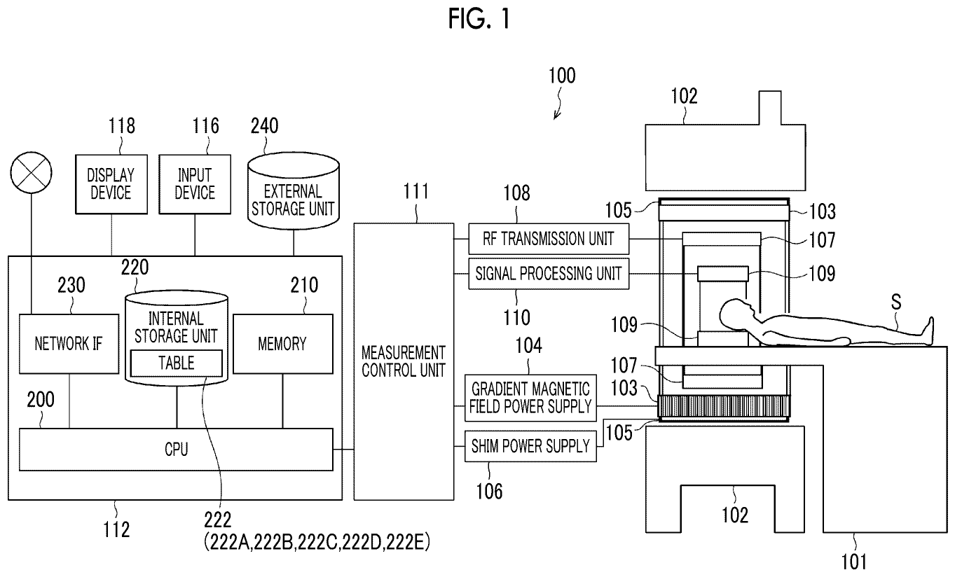

FIG. 1 is a block diagram showing an overall configuration of an embodiment of a magnetic resonance imaging apparatus 100. Hereinafter, the magnetic resonance imaging apparatus 100 will be referred to as a magnetic resonance imaging (MRI) apparatus 100.

The MRI apparatus 100 obtains a tomographic image of a subject S by using a nuclear magnetic resonance (NMR) phenomenon. The MRI apparatus 100 comprises a bed 101, a static magnetic field generating magnet 102, a gradient magnetic field coil 103 and a gradient magnetic field power supply 104, a shim coil 105 and a shim power supply 106, a radio frequency (RF) transmission coil 107 and an RF transmission unit 108, an RF reception coil 109 and a signal processing unit 110, a measurement control unit 111, an overall controller 112, an input device 116, and a display device 118.

The bed 101 comprises a top plate on which the subject S is placed. The bed 101 causes the top plate to enter a static magnetic field space of the static magnetic field generating magnet 102 and to exit the static magnetic field space by using a drive mechanism (not shown).

The static magnetic field generating magnet 102 functions as a “static magnetic field generating device” of the present disclosure. The static magnetic field generating magnet 102 generates a uniform static magnetic field in each of a direction orthogonal to a body axis of the subject S in a case of a vertical magnetic field method and a body axis direction in a case of a horizontal magnetic field method. The static magnetic field generating magnet 102 includes a static magnetic field generating source of a permanent magnet type, a normal conducting type, or a superconducting type. The static magnetic field generating source is disposed around the subject S.

The gradient magnetic field coil 103 and the gradient magnetic field power supply 104 function as a “gradient magnetic field generating device” of the present disclosure. The gradient magnetic field coil 103 is a coil wound in three-axis directions of X, Y, and Z, which are a real space coordinate system (stationary coordinate system) of the MRI apparatus 100. Each gradient magnetic field coil is connected to the gradient magnetic field power supply 104 and is supplied with a current. Specifically, the gradient magnetic field power supply 104 of each gradient magnetic field coil is driven in accordance with a command from the measurement control unit 111 and supplies a current to each gradient magnetic field coil. As a result, gradient magnetic fields Gx, Gy, and Gz are generated in the three-axis directions of X, Y, and Z.

In a case of imaging a two-dimensional slice plane, a slice gradient magnetic field pulse (Gs) is applied in a direction orthogonal to a slice plane (imaging cross-section) to set the slice plane for the subject S, and a phase encoding gradient magnetic field pulse (Gp) and a frequency encoding (readout) gradient magnetic field pulse (Gf) are applied in the remaining two directions, which are orthogonal to the slice plane and orthogonal to each other, thereby encoding position information in each direction into the nuclear magnetic resonance signal (echo signal).

The shim coil 105 and the shim power supply 106 function as a “compensation magnetic field generating device” of the present disclosure that corrects static magnetic field inhomogeneity. The shim coil 105 is composed of a coil that can generate a magnetic field having a spatial distribution that follows the first-order gradient magnetic field and zero-order or higher spherical harmonic functions such as Z², XY, ZY, or XZ. The shim coil 105 is connected to the shim power supply 106 and generates a magnetic field in order to improve static magnetic field homogeneity by using a compensation current supplied from the shim power supply 106.

The gradient magnetic field coil 103 may also be used as the compensation magnetic field generating device for the first-order gradient magnetic field. In this case, the gradient magnetic field power supply 104 supplies a compensation current for generating a correction magnetic field to the gradient magnetic field coil 103, with the compensation current superimposed on a gradient magnetic field current for imparting the above-mentioned position information.

The RF transmission coil 107 and the RF transmission unit 108 function as a “transmission device” of the present disclosure. The RF transmission coil 107 is a coil that irradiates the subject S with an RF pulse (an example of a “high-frequency magnetic field pulse”). The RF transmission coil 107 is connected to the RF transmission unit 108 and is supplied with a high-frequency pulse current. Consequently, the NMR phenomenon is induced in the spins of the atoms constituting the biological tissue of the subject S. Specifically, the RF transmission unit 108 is driven in accordance with a command from the measurement control unit 111 to amplitude-modulate a high-frequency pulse and supply the amplified high-frequency pulse to the RF transmission coil 107 disposed close to the subject S, thereby irradiating the subject S with the RF pulse.

The RF reception coil 109 and the signal processing unit 110 function as a “reception device” of the present disclosure. The RF reception coil 109 is a coil that receives an echo signal emitted by the NMR phenomenon of the spins constituting the biological tissue of the subject S. The RF reception coil 109 is connected to the signal processing unit 110. The echo signal received by the RF reception coil 109 is transmitted to the signal processing unit 110.

The signal processing unit 110 performs detection processing of the echo signal received by the RF reception coil 109. Specifically, the signal processing unit 110 amplifies the received echo signal in accordance with a command from the measurement control unit 111, splits the echo signal into two orthogonal systems of signals through quadrature phase detection, samples each of the two orthogonal systems of signals a predetermined number of times (for example, 128, 256, 512, and the like), and converts each sampled signal into a digital quantity through A/D conversion. Therefore, the echo signal is obtained as time series digital data (hereinafter, referred to as echo data) consisting of a predetermined number of pieces of sampling data. Then, the signal processing unit 110 performs various types of processing on the echo data and transmits the processed echo data to the measurement control unit 111.

The measurement control unit 111 transmits various commands for acquiring echo data necessary for the reconstruction of the tomographic image of the subject S mainly to the gradient magnetic field power supply 104, the RF transmission unit 108, and the signal processing unit 110 to control the gradient magnetic field power supply 104, the RF transmission unit 108, and the signal processing unit 110 based on control data of a pulse sequence included in the imaging protocol, under the control of the overall controller 112. That is, the measurement control unit 111 repeatedly executes the irradiation of the RF pulse and the application of the gradient magnetic field pulse to the subject S and the detection of the echo signal from the subject S, and controls the acquisition of the echo data necessary for the reconstruction of an image for an imaging region of the subject S.

During repetition, the measurement control unit 111 changes an application amount of the phase encoding gradient magnetic field by the phase encoding number in a case of two-dimensional imaging and further changes an application amount of the slice encoding gradient magnetic field in a case of three-dimensional imaging. The number of phase encodings is typically selected as values such as 128, 256, or 512 per image, and the number of slice encodings is typically selected as values such as 16, 32, or 64. The measurement control unit 111 outputs the echo data from the signal processing unit 110 to the overall controller 112 through the control.

The overall controller 112 performs control of the measurement control unit 111, various types of data processing, and control of display, storage, and the like of processing results. The overall controller 112 can be constructed on a computer comprising a central processing unit (CPU) 200, a memory 210, and an internal storage unit 220 such as a magnetic disk, or on a workstation. Some functions of the overall controller 112 may be implemented by hardware such as an ASIC or an FPGA. The overall controller 112 comprises a network interface (IF) 230 that interfaces with an external network. An external storage unit 240 such as an optical disk may be connected to the overall controller 112.

Specifically, the overall controller 112 causes the measurement control unit 111 to acquire the echo data by executing the pulse sequence. In a case in which the echo data from the measurement control unit 111 is input, the overall controller 112 stores the echo data in a region corresponding to a k-space in the memory 210 based on encoding information applied to the echo data by the CPU 200.

The CPU 200 executes signal processing on k-space data and processing of image reconstruction using Fourier transform and the like. In addition, the CPU 200 displays the image of the subject S, which is a result of the image reconstruction processing, on the display device 118, records the image on the memory 210 and the external storage unit 240, or transmits the image to an external device via the network IF 230.

The internal storage unit 220 stores a table 222 and the like, which will be described below.

The input device 116 includes a trackball, a mouse, a keyboard, and the like for inputting various types of control information of the MRI apparatus 100 and control information of processing performed by the above-described overall controller 112. The display device 118 includes a display that displays the reconstructed image of the subject S. The input device 116 and the display device 118 are disposed close to each other, and the user interactively controls various types of processing of the MRI apparatus 100 via the input device 116 while looking at the display device 118.

In the MRI apparatus 100, the CPU 200 has, in addition to a function as an image generation unit that performs the above-mentioned image reconstruction, a function of acquiring data for static magnetic field correction for a compensation magnetic field generation unit to correct static magnetic field inhomogeneity.

### First Embodiment

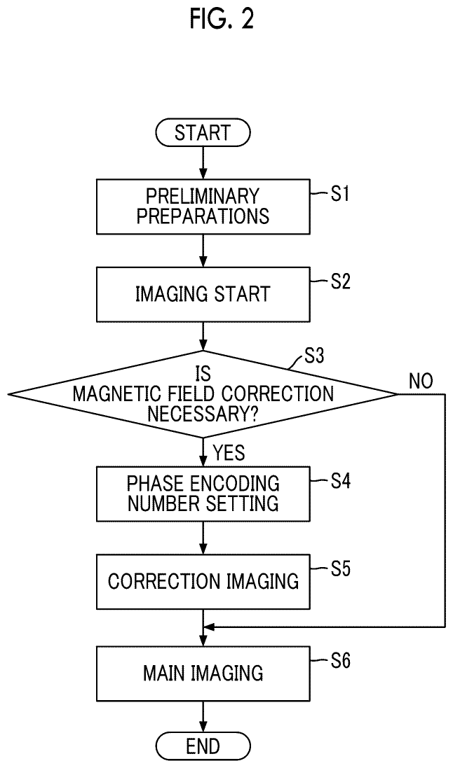

FIG. 2 is a flowchart showing steps of an imaging method which is an example of a control method of the MRI apparatus 100.

In step S1, the user performs preliminary preparations of the MRI apparatus 100. As the preliminary preparations, the user registers subject information of the subject S by using the input device 116. In addition, the user inputs the imaging site of the subject S by using the input device 116. The imaging site may be input by the user by selecting from among a plurality of imaging sites displayed in a selectable manner on the display device 118 using the input device 116. Further, the user places the subject S on the top plate of the bed 101 and causes the top plate to enter the interior of the static magnetic field generating magnet 102 such that the subject S can be imaged.

Additionally, the overall controller 112 reads out the imaging protocol based on the input subject information, imaging site, and the like from the internal storage unit 220. The imaging protocol includes the pulse sequence. The pulse sequence includes a second phase encoding number, which is an encoding number in a phase direction during main imaging (the number of phase encoding gradient magnetic field pulses per slice).

In step S2, the MRI apparatus 100 starts imaging. The imaging includes correction imaging and main imaging. In a case in which the user presses an imaging start button by using the input device 116 after adjusting an imaging condition, the imaging by the MRI apparatus 100 starts.

In step S3, the MRI apparatus 100 automatically determines whether or not magnetic field correction for correcting the static magnetic field is necessary. Here, the overall controller 112 determines whether or not the magnetic field correction is necessary, based on the imaging protocol read out in step S1. For example, the overall controller 112 determines whether or not the imaging protocol includes any of fat suppression of a chemical shift selective (CHESS) method, an echo planar imaging (EPI) method, or a balance-type GrE sequence, and determines that the magnetic field correction is unnecessary in a case in which none of the methods are included and determines that the magnetic field correction is necessary in a case in which any of the methods is included. The MRI apparatus 100 transitions to the processing of step S6 in a case in which the magnetic field correction is unnecessary, and transitions to the processing of step S4 in a case in which the magnetic field correction is necessary.

In step S4, the overall controller 112 determines an imaging range. For example, the overall controller 112 acquires a positioning image of a body axis cross-section and determines the imaging range in a body axis cross-section direction from the imaging site input in step S1. The imaging range may be manually input by the user using the input device 116.

Further, in step S4, the MRI apparatus 100 sets a first phase encoding number Np, which is the encoding number in the phase direction during acquisition of the data for static magnetic field correction (during correction imaging). In the table 222 stored in the internal storage unit 220, the Np and the imaging site are stored in association with each other. The Np stored in the table 222 is a minimum required phase encoding number corresponding to the imaging site and is a phase encoding number smaller than the second phase encoding number. The overall controller 112 determines the Np corresponding to the imaging site input in step S1 by referring to the table 222.

In a region such as an abdomen, which is large in size and has mild magnetic field distortion, the magnetic field distortion can be reproduced even with low resolution. Therefore, a relatively small value is employed for the Np. On the other hand, in a region such as a neck, which is small in size and has steep magnetic field distortion, it is necessary to increase the resolution in order to reproduce the magnetic field distortion. Therefore, a relatively large value is employed for the Np.

In step S5, the MRI apparatus 100 performs the correction imaging and acquires first echo data (an example of a “first nuclear magnetic resonance signal”) as the correction data. That is, the overall controller 112 controls the operations of the transmission device, the reception device, and the gradient magnetic field generating device to perform imaging with the Np determined in step S4 for the imaging range determined in step S4.

Finally, in step S6, the MRI apparatus 100 performs the main imaging. That is, the overall controller 112 controls the transmission device, the reception device, and the gradient magnetic field generating device and controls the compensation magnetic field generating device based on the first echo data to acquire second echo data (an example of a “second nuclear magnetic resonance signal”). The main imaging in a case of transitioning from step S5 is performed for the imaging range determined in step S4, based on the imaging protocol read out in step S1 with a parameter set to reflect the first echo data acquired in step S5. The main imaging in a case of transitioning from step S3 is performed for the imaging range determined in advance based on the imaging protocol read out in step S1. Since the second phase encoding number is greater than the first phase encoding number, the main imaging is performed with higher resolution than the correction imaging.

Further, the overall controller 112 reconstructs the image based on the second echo data acquired by the main imaging. As a result, in a case in which the magnetic field correction is necessary, the MRI apparatus 100 can acquire an image in which the static magnetic field is corrected.

In order to improve examination efficiency, it is desired to shorten the time spent on the acquisition of data for magnetic field correction, which is not used for diagnosis, as much as possible. According to the first embodiment, whether or not the magnetic field correction is necessary is determined, and the correction imaging is not performed in a case in which the magnetic field correction is unnecessary, thereby contributing to shortening the duration of confinement for the subject. In addition, according to the first embodiment, in a case in which the magnetic field correction is necessary, in-plane resolution of the correction imaging for acquiring the correction data is set to the minimum required resolution according to the imaging site of the subject. Therefore, the amount of data acquisition for the correction imaging is the minimum required amount of data acquisition corresponding to the imaging site, thereby contributing to shortening the duration of confinement for the subject.

### First Modification Example of First Embodiment

The internal storage unit 220 of the overall controller 112 may store a table 222A instead of the table 222. The table 222A includes a plurality of tables corresponding to the age, the sex, and the height and weight (body type) of the subject. The overall controller 112 can select one table from among the plurality of tables based on the registered subject information including at least one of the age, the sex, or the body type of the subject and can determine the Np by referring to the selected table.

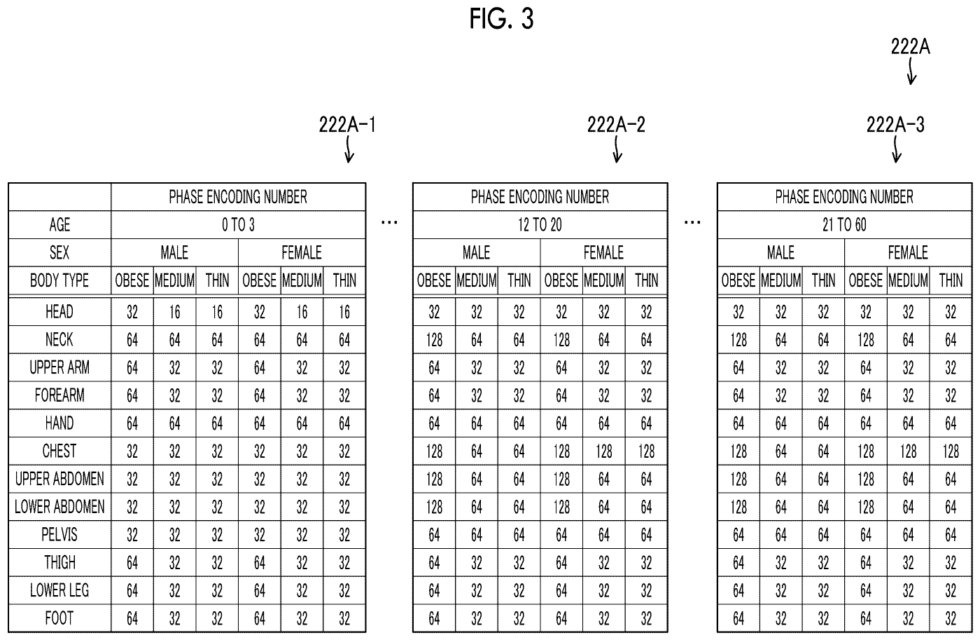

FIG. 3 is a diagram showing an example of the table 222A. In the example shown in FIG. 3, the table 222A is a table showing Np in a case in which a head-foot direction (H-F direction) for each imaging site is the phase direction, and includes age-specific tables 222A-1, 222A-2, and 222A-3. The age-specific tables 222A-1, 222A-2, and 222A-3 are tables in which the ages [years] are “0 to 3”, “12 to 20”, and “21 to 60”, respectively. The table 222A may include age-specific tables for “4 to 11” and “61 and older”. The age-specific tables 222A-1, 222A-2, and 222A-3 are each further classified by the sex (male/female) and the body type (obese/medium/thin).

The body type is classified according to the body mass index (BMI) as “obese” for BMI>25, “medium” for 25>BMI≥18.5, and “thin” for 18.5<BMI. The BMI is calculated by BMI=w/h² in a case in which the height is denoted by h [m] and the weight is denoted by w [kg].

The BMI may be registered in advance or may be acquired from a hospital information system (HIS) or a radiology information system (RIS).

As shown in FIG. 3, according to the age-specific table 222A-1, in a case in which the age is “0 to 3”, the sex is “male”, the body type is “medium”, and the imaging site is “head”, the Np is “16”. Meanwhile, in a case in which the age is “0 to 3”, the sex is “male”, the body type is “medium”, and the imaging site is “neck”, the Np is “64”. In this manner, even in a case in which the age, the sex, and the body type are the same, the Np may be different depending on the imaging site.

Additionally, according to the age-specific table 222A-1, in a case in which the age is “0 to 3”, the sex is “male”, the body type is “obese”, and the imaging site is “head”, the Np is “32”. Meanwhile, in a case in which the age is “0 to 3”, the sex is “male”, the body type is “medium”, and the imaging site is “head”, the Np is “16”. In this manner, even in a case in which the age, the sex, and the imaging site are the same, the Np may be different depending on the body type. In this example, a relatively higher BMI corresponds to a relatively greater Np.

In addition, according to the age-specific table 222A-2, in a case in which the age is “12 to 20”, the sex is “male”, the body type is “medium”, and the imaging site is “chest”, the Np is “64”. Meanwhile, in a case in which the age is “12 to 20”, the sex is “female”, the body type is “medium”, and the imaging site is “chest”, the Np is “128”. In this manner, even in a case in which the age, the body type, and the imaging site are the same, the Np may be different depending on the sex.

Further, according to the age-specific table 222A-1, in a case in which the age is “0 to 3”, the sex is “female”, the body type is “obese”, and the imaging site is “neck”, the Np is “64”. Meanwhile, according to the age-specific table 222A-2, in a case in which the age is “12 to 20”, the sex is “female”, the body type is “obese”, and the imaging site is “neck”, the Np is “128”. In this manner, even in a case in which the sex, the body type, and the imaging site are the same, the Np may be different depending on the age.

According to the first modification example of the first embodiment, the amount of data acquisition for the correction imaging can be set to the minimum required amount of data acquisition corresponding to the subject information. The subject information need only include at least one of the age, the sex, or the body type.

### Second Modification Example of First Embodiment

The overall controller 112 may determine the Np based on not only the imaging site but also the size of the imaging site. The internal storage unit 220 of the overall controller 112 may store a table in which a size category of the imaging site of the subject and the Np correspond to each other.

The overall controller 112 may acquire the size of the imaging site of the subject from the positioning image (an example of a “captured image”) acquired in step S4 of the first embodiment. For example, in a case in which the positioning image is a body axis cross-sectional image, the overall controller 112 acquires a size Y_{AP} in an anterior-posterior direction (A-P direction) and a size X_{RL} in a right-left direction (R-L direction) of the imaging site of the subject. The overall controller 112 performs only the frequency encoding in a state in which phase encoding is not applied in each direction (a state in which the phase encoding gradient magnetic field is set to zero) during the acquisition of the positioning image. Then, the overall controller 112 defines a range of the profile of the resulting image obtained by Fourier transform of the acquired data, which is equal to or greater than a threshold value, as a region where the subject is present, and sets the size of the region as Y_{AP} and X_{RL}.

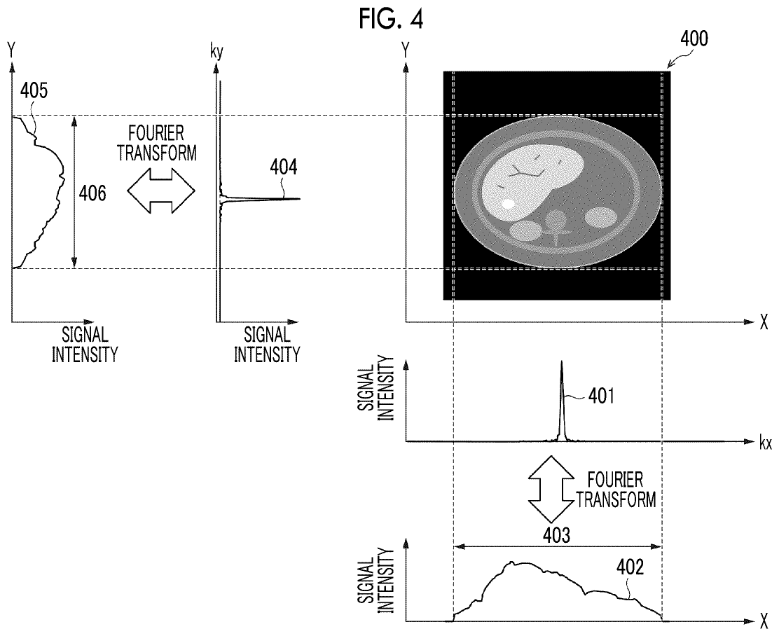

FIG. 4 is a diagram illustrating the acquisition of the size of the imaging site of the subject. 400 shown in FIG. 4 shows an XY cross-section of the imaging site in a case in which the R-L direction of the subject S is an X direction and the A-P direction is a Y direction.

401 shown in FIG. 4 is echo data acquired by applying frequency encoding only in the X direction in a state in which phase encoding is not applied, in which a horizontal axis indicates a spatial frequency, and a vertical axis indicates a signal intensity.

402 shown in FIG. 4 is a profile of a result of Fourier transform of the data 401, in which a horizontal axis indicates the X direction corresponding to the position of the XY cross-section 400, and a vertical axis indicates a signal intensity. Additionally, 403 shown in FIG. 4 is a range in which the profile 402 is equal to or greater than the threshold value. The overall controller 112 defines the range 403 as a region where the subject is present, and sets a size of the region as X_{RL}.

404 shown in FIG. 4 is echo data acquired by applying frequency encoding only in the Y direction in a state in which phase encoding is not applied, in which a vertical axis indicates a spatial frequency and a horizontal axis indicates a signal intensity.

405 shown in FIG. 4 is a profile of a result of Fourier transform of the data 404, in which a vertical axis indicates the Y direction corresponding to the position of the XY cross-section 400, and a horizontal axis indicates a signal intensity. In addition, 406 shown in FIG. 4 is a range in which the profile 405 is equal to or greater than the threshold value. The overall controller 112 defines the range 406 as a region where the subject is present, and sets a size of the region as Y_{AP}.

In this manner, the overall controller 112 can acquire the size of the imaging site of the subject from the positioning image. Therefore, the overall controller 112 can determine the Np by referring to the table in which the size category of the imaging site and the Np correspond to each other, based on the size of the imaging site of the subject.

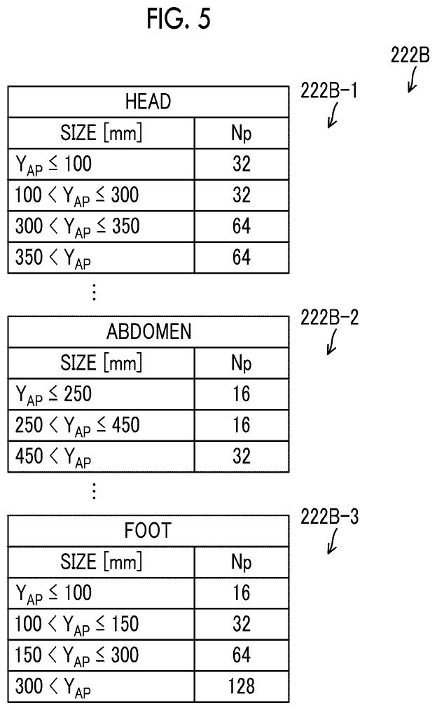

FIG. 5 is a diagram showing a table 222B in which the size category of the imaging site and the Np correspond to each other. The table 222B is stored in the internal storage unit 220 of the overall controller 112. The table 222B includes imaging site-specific tables 222B-1, 222B-2, and 222B-3. The imaging site-specific tables 222B-1, 222B-2, and 222B-3 are tables in which the imaging sites are “head”, “abdomen”, and “foot”, respectively. Although not shown here, the table 222B includes a table for each imaging site, such as “neck”, “upper arm”, and “forearm”, in addition to “head”, “abdomen”, and “foot”.

In the table 222A shown in FIG. 3, the imaging site and the minimum required Np are associated with each other, but in the table 222B, the category of the size Y_{AP} and Np are associated with each other for each imaging site. For example, according to the imaging site-specific table 222B-1, in a case in which the imaging site is “head” and the size Y_{AP} is “200 mm”, the Np is “32”. Additionally, according to the imaging site-specific table 222B-2, in a case in which the imaging site is “abdomen” and the size Y_{AP} is “300 mm”, the Np is “16”.

The overall controller 112 can determine the Np by referring to the table 222B from the imaging site input in step S1 and the size Y_{AP} described using FIG. 4. In the table 222B, the size Y_{AP} is used as the size category of the imaging site, but the size X_{RL}, the size Z_{HF}, or a combination thereof may be used as the size category.

The size of the imaging site of the subject may be registered in advance. In addition, the size of the imaging site of the subject may be acquired from the height and weight of the subject acquired from the HIS or the RIS.

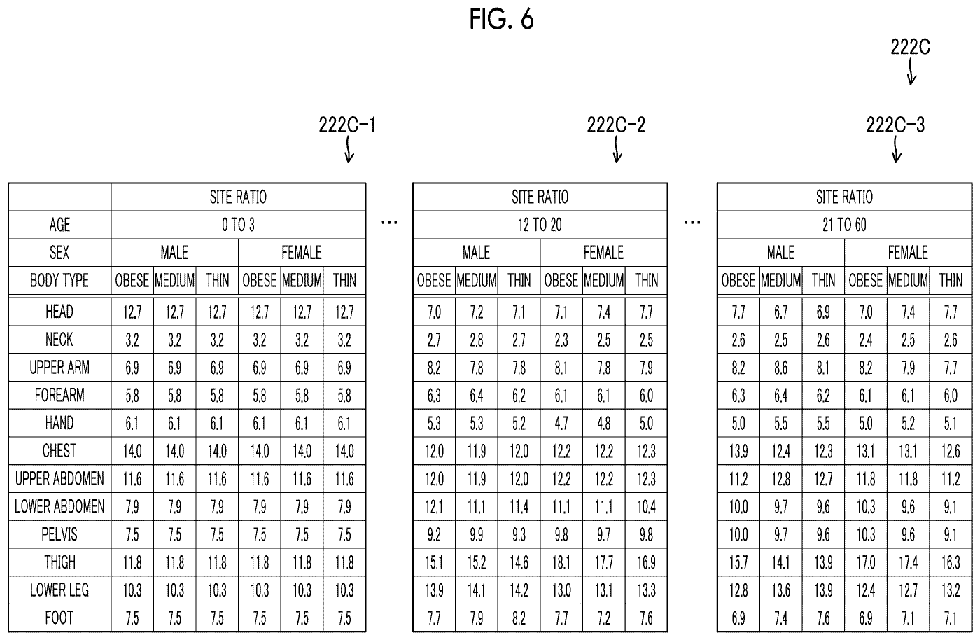

FIG. 6 is a diagram showing an example of a table 222C for obtaining the size of the imaging site from the subject information. The table 222C shows a ratio [%] in the H-F direction for each imaging site and includes age-specific tables 222C-1, 222C-2, and 222C-3. The age-specific tables 222C-1, 222C-2, and 222C-3 are tables in which the ages are “0 to 3”, “12 to 20”, and “21 to 60”, respectively. The table 222C may include age-specific tables for 4 to 11 and 61 and older. The age-specific tables 222C-1, 222C-2, and 222C-3 are each further classified by the sex (male/female) and the body type (obese/medium/thin).

For example, according to the age-specific table 222C-1, in a case in which the age is “0 to 3”, the sex is “male”, the body type is “obese”, and the imaging site is “head”, the site ratio is “12.7”. In the age-specific table 222C-1, the total of the site ratios may exceed 100 [%]. This is because, for example, there is an overlapping portion between the upper arm and forearm, and the chest, abdomen, and the like.

The overall controller 112 can calculate the size ZHF in the H-F direction of the imaging site of the subject by multiplying the acquired height of the subject by the site ratio acquired by referring to the table 222C. Therefore, the overall controller 112 can determine the Np by referring to the table in which the size category of the imaging site and the Np correspond to each other, based on the size of the imaging site of the subject.

The size can be acquired by preparing the same table as the table 222A for the A-P direction and the R-L direction of the imaging site of the subject.

According to the second modification example of the first embodiment, the amount of data acquisition for the correction imaging can be set to the minimum required amount of data acquisition corresponding to the size of the imaging site of the subject.

Here, the length [m] in each direction is used as the size, but the size may be a body surface area [m²]. For example, the overall controller 112 may determine the phase encoding number corresponding to the body surface area of the imaging site by obtaining the body surface area of the imaging site from a table of the body surface area and the site ratio of an entire body of the subject. The site ratio of the body surface area is described in, for example, Shigeki Fujimoto, Tsutomu Watanabe, Koichi Yukawa, Atsushi Sakamoto (1968), “Studies on the Physical Surface Area of Japanese, Part 17: Sex, Age, Body Type, and Site Ratios”, the Japanese Society for Hygiene, 23(5), pp. 437 to 442.

### Second Embodiment

In the first embodiment, it is assumed that the imaging site is manually selected and input by the user. In the second embodiment, the imaging site is automatically categorized from preliminary imaging of the entire body, and the Np is determined for the imaging site selected by the user.

Specifically, the overall controller 112 acquires a positioning image of the entire body of the subject as the preliminary imaging. The positioning image may be a cross-sectional image in each of the A-P direction, the R-L direction, and the H-F direction. Next, the overall controller 112 categorizes imaging sites in the body axis direction from the acquired positioning image of the entire body. The imaging sites to be categorized include, for example, the head, neck, shoulders, thoracic body, abdominal body, hip joints, upper legs, lower legs, and feet.

Next, the overall controller 112 displays the categorized imaging sites on the display device 118 and allows the user to select any of the imaging sites. Subsequent processing is the same as that of the first embodiment.

The overall controller 112 may display the positioning image of the entire body on the display device 118 and recognize the imaging range manually selected by the user using the input device 116 for the displayed positioning image as the imaging site.

According to the second embodiment, the imaging site can be easily selected by the user.

### Modification Example of Second Embodiment

In the second embodiment, the imaging site is selected by the user; however, the overall controller 112 may automatically determine the first phase encoding number of each imaging site in the entire section and may perform imaging entirely automatically.

### Third Embodiment

In the third embodiment, a minimum number based on at least one of the resolution or the magnetic field distortion is set between the imaging site and the first phase encoding number. The third embodiment may be performed in any of the second modification example of the first embodiment, the second embodiment, and the modification example of the second embodiment, in which the size information of the subject is acquired.

### In Case of Resolution

The internal storage unit 220 of the overall controller 112 stores a table 222D instead of the table 222. The table 222D holds the minimum resolution δ (mm/px) for each imaging site. The minimum number of the phase encoding number required is determined according to the minimum resolution δ.

The overall controller 112 determines the minimum Np that satisfies δ>(Y_{AP}/Np). Due to the reconstruction requirements, the Np takes discrete values of 2ⁿ×k (k is a natural number). For example, in a case in which n=3, the Np is 8, 16, 32, . . . . Therefore, the overall controller 112 determines the minimum Np among the settable discrete values.

### In Case of Magnetic Field Distortion

The internal storage unit 220 of the overall controller 112 stores a table 222E instead of the table 222. The table 222E holds the maximum magnetic field distortion a [Hz/m] that may occur per unit distance for each imaging site. The minimum number N of the phase encoding number required is determined according to the magnetic field distortion α. The overall controller 112 determines the minimum Np that satisfies N<Np.

A procedure of determining the Np from the magnetic field distortion α will be described. It is necessary to set the resolution high (the phase encoding number high) in order to express a significant magnetic field distortion, that is, a steep distortion. Therefore, in a case in which the maximum frequency resolution that can be expressed by the MRI apparatus 100 is denoted by β [Hz], α [Hz/m]×Y_{AP} [m]/β [Hz] is the minimum phase encoding number required.

In a case of creating a static magnetic field map, data is acquired at two different echo times (TEs), but in a case in which the difference ΔTE between the two TEs rotates by 2π or greater, the magnetic field cannot be accurately expressed. Therefore, the maximum value of the frequency difference between pixels needs to be equal to or less than 1/ΔT [Hz].

However, as mentioned above, due to the reconstruction requirements, the Np takes discrete values of 2ⁿ×k (k is a natural number). Therefore, the Np is set to a value equal to or greater than the minimum phase encoding number calculated by the above-described equation and corresponds to the minimum discrete value.

According to the third embodiment, the first phase encoding number based on at least one of the resolution or the magnetic field distortion can be set.

### Fourth Embodiment

In the fourth embodiment, in a case in which there is a site having body motion in the selected imaging site, the first phase encoding number is controlled such that the imaging of the imaging site is completed within a body motion period. The body motion is determined by the type for each imaging site; for example, in a case in which the imaging site is the abdomen, it may include respiratory motion and peristalsis.

An imaging method according to the fourth embodiment will be described using a flowchart of FIG. 2. The processing of steps S1 to S3 is the same as that of the first embodiment.

In step S4, the overall controller 112 determines the Np from the minimum phase encoding number obtained from the size Y_{AP} in the A-P direction or the size X_{RL} in the R-L direction of the imaging site of the subject and the maximum phase encoding number allowed from an occurrence time interval of the body motion of the imaging site.

NpMIN, which is the minimum phase encoding number, is determined as follows. First, the overall controller 112 determines a required minimum number N according to the magnetic field distortion per unit distance in the imaging site. Then, the overall controller 112 calculates Np, which is the minimum integer that satisfies N<Y_{AP}/Np, as the NpMIN in a case in which the phase encoding direction of the correction imaging is the A-P direction, and calculates Np, which is the minimum integer that satisfies N<X_{RL}/Np, as the NpMIN in a case in which the phase encoding direction of the correction imaging is the R-L direction. The minimum number N may be determined according to the resolution.

NpMAX, which is the maximum phase encoding number, is determined as follows. The internal storage unit 220 of the overall controller 112 holds the occurrence time interval of the body motion corresponding to the type of the body motion for each imaging site. The overall controller 112 acquires an occurrence time interval Tm (seconds) of the body motion in the imaging site acquired in step S1 from the internal storage unit 220. Then, the overall controller 112 calculates the NpMAX, which is the maximum phase encoding number allowed, from the occurrence time interval Tm and the time allowed for imaging.

Here, in a case in which the number of slices to be imaged is denoted by Slice#and a repetition time of an excitation RF pulse, which will be described below, is denoted by TR, the imaging time of the MRI apparatus 100 is generally determined by Np×Slice#×TR.

Therefore, the overall controller 112 first determines the number of slices in order to calculate the imaging time. In a case in which the size of the imaging site in the H-F direction, which is the slice direction of the subject, is denoted by Z_{HF} and a slice thickness is denoted by Thick, the overall controller 112 calculates Slice#, which is the minimum integer that satisfies Slice#>Z_{HF}/Thick, as a required slice number Slice#MIN. The values stored in the internal storage unit 220 of the overall controller 112 in advance need only be used as Thick and TR. Then, the overall controller 112 sets Np, which is the maximum integer that satisfies Np×Slice#MIN×TR<Tm, as the NpMAX.

Subsequently, the overall controller 112 determines the Np according to the magnitude relationship between NpMIN and NpMAX.

Since it is preferable that the time of the correction imaging is short, it is preferable that the Np is small. Therefore, in a case in which NpMIN≤NpMAX, NpMIN=Np.

On the other hand, in a case in which NpMIN>NpMAX, NpMAX=Np is set in a case in which the resolution is prioritized, and NpMIN=Np is set in a case in which the body motion is prioritized. The user may be allowed to select whether to prioritize the resolution or the body motion.

Finally, in step S5, the MRI apparatus 100 performs the correction imaging with the Np determined in step S4 and acquires the first echo data. Further, in step S6, the MRI apparatus 100 performs the main imaging included in various protocols in which the parameter reflecting the first echo data is set, and acquires the second echo data.

In a case in which the correction data is mixed with the influence such as artifacts caused by the subject's body motion within the body, there is a possibility of correction failure. Therefore, it is desired to reduce the influence of the body motion such as peristalsis as much as possible. In the imaging method according to the fourth embodiment, the in-plane resolution is determined such that it falls within the data acquisition time allowed for the acquisition of the correction data, by using the fact that the type of the body motion is determined for each site. According to the fourth embodiment, it is possible to acquire the correction data with reduced influence of the body motion.

### Pulse Sequence

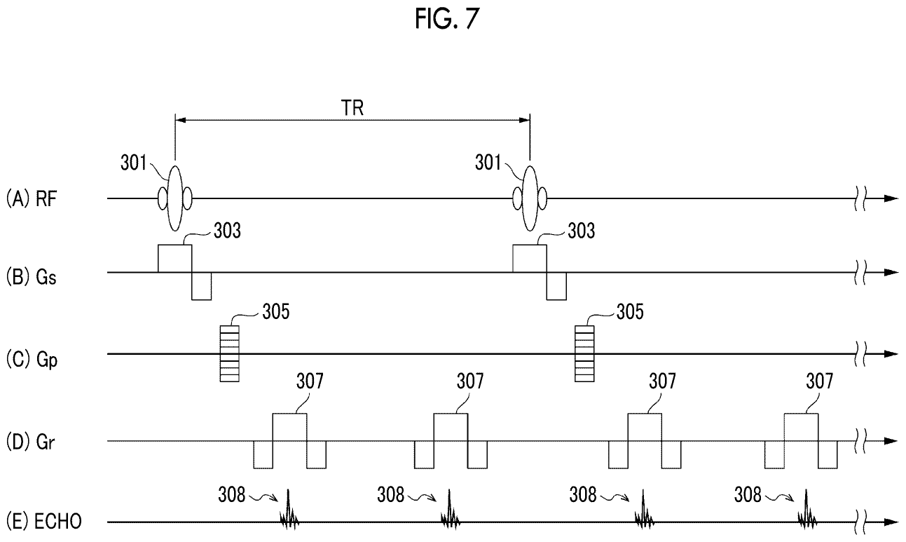

FIG. 7 is a diagram showing an example of a multi-echo gradient echo sequence performed in the MRI apparatus 100. (A) of FIG. 7 shows the application timing of the RF pulse, (B), (C), and (D) of FIG. 7 show the application timings of the gradient magnetic field pulses in the slice direction, the phase encoding direction, and the readout direction, respectively, and (E) of FIG. 7 shows the acquisition timing of the echo signal.

As described in Tsutomu Araki, “MRI Essentials Power Text, 3rd Edition”, Medical Science International Co., Ltd., 2011, p. 182, the imaging time is determined by Imaging time=TR×phase encoding number×NEX. NEX is the number of times the entire sequence is repeated.

As shown in FIG. 7, in the multi-echo gradient echo sequence, an excitation RF pulse 301 is applied together with a slice selection gradient magnetic field 303 to excite a desired slice. Then, after a phase encoding gradient magnetic field 305 is applied, a readout gradient magnetic field 307 is continuously applied for the number of multi-echoes, and a main echo signal 308 is collected during the application of the readout gradient magnetic field 307.

In the multi-echo gradient echo sequence, the excitation RF pulse is repeatedly generated at a time interval of TR, and the collected main echo signal 308 is stored in a region corresponding to the k-space in the memory 210.

### Configuration of Overall Controller

A hardware structure of the overall controller 112 is various processors as described below. The various processors include a central processing unit (CPU), which is a general-purpose processor that executes software (programs) and acts as various functional units, a graphics processing unit (GPU), which is a processor specialized for image processing, a programmable logic device (PLD), which is a processor that allows a circuit configuration to be changed after manufacturing, such as a field-programmable gate array (FPGA), and a dedicated electrical circuit, which is a processor that is designed with a circuit configuration specifically for executing specific processing, such as an application specific integrated circuit (ASIC).

One processing unit may be configured with one of the various processors or may be configured with two or more processors of the same type or different types (for example, a combination of a plurality of FPGAs, a combination of a CPU and an FPGA, or a combination of a CPU and a GPU). Alternatively, a plurality of functional units may be configured with one processor. As an example of configuring the plurality of functional units with one processor, first, there is an aspect in which one or more CPUs are combined with software to constitute one processor and the processor acts as the plurality of functional units, as represented by a computer, such as a client or a server. Second, there is an aspect in which a processor that implements functions of an entire system, which includes the plurality of functional units, with one integrated circuit (IC) chip is used, as represented by a system on chip (SoC) and the like. In this manner, various functional units are configured as a hardware structure using one or more of the above-described various processors.

Furthermore, the hardware structure of these various processors is more specifically an electrical circuit (circuitry) in which circuit elements such as semiconductor elements are combined.

### Others

The technical scope of the present invention is not limited to the scope described in the above-described embodiments. The configurations and the like in each of the embodiments can be appropriately combined among the embodiments without departing from the gist of the present invention.

### EXPLANATION OF REFERENCES

100: MRI apparatus
101: bed
102: static magnetic field generating magnet
103: gradient magnetic field coil
104: gradient magnetic field power supply
105: shim coil
106: shim power supply
107: RF transmission coil
108: RF transmission unit
109: RF reception coil
110: signal processing unit
111: measurement control unit
112: overall controller
116: input device
118: display device

What is claimed is:

1. A magnetic resonance imaging apparatus comprising:
a static magnetic field generating device that generates a static magnetic field;
a transmission device that irradiates a subject placed in a static magnetic field space with a high-frequency magnetic field pulse;
a reception device that receives a nuclear magnetic resonance signal generated from the subject by the irradiation of the high-frequency magnetic field pulse;
a gradient magnetic field generating device that generates a gradient magnetic field in the static magnetic field space;
a compensation magnetic field generating device that corrects inhomogeneity of the static magnetic field; and
at least one processor,
wherein the processor is configured to:
acquire an imaging site of the subject;
set a first phase encoding number corresponding to the acquired imaging site;
control operations of the transmission device, the reception device, and the gradient magnetic field generating device to acquire a first nuclear magnetic resonance signal with the first phase encoding number;
control the operations of the transmission device, the reception device, and the gradient magnetic field generating device and control the compensation magnetic field generating device based on the first nuclear magnetic resonance signal to acquire a second nuclear magnetic resonance signal with a second phase encoding number greater than the first phase encoding number; and
reconstruct an image of the subject based on the second nuclear magnetic resonance signal.

2. The magnetic resonance imaging apparatus according to claim 1,
wherein the processor is configured to:
acquire an imaging protocol; and
acquire the first nuclear magnetic resonance signal in a case in which the acquired imaging protocol requires correction of the static magnetic field.

3. The magnetic resonance imaging apparatus according to claim 1,
wherein a table in which the imaging site of the subject and the first phase encoding number are stored in association with each other is provided, and
the processor is configured to set the first phase encoding number by referring to the table.

4. The magnetic resonance imaging apparatus according to claim 1,
wherein the processor is configured to:
acquire information including at least one of an age, a sex, or a body type of the subject; and
set the first phase encoding number according to the acquired information.

5. The magnetic resonance imaging apparatus according to claim 1,
wherein the processor is configured to:
acquire a size of the imaging site of the subject; and
set the first phase encoding number according to the acquired size.

6. The magnetic resonance imaging apparatus according to claim 5,
wherein the processor is configured to:
acquire a captured image of the subject; and
acquire a size of the imaging site from the acquired captured image.

7. The magnetic resonance imaging apparatus according to claim 6,
wherein the processor is configured to:
acquire a captured image of an entire body of the subject; and
acquire the size of the imaging site from a ratio of the imaging site to the entire body.

8. The magnetic resonance imaging apparatus according to claim 1,
wherein the processor is configured to:
acquire a captured image of an entire body of the subject;
display the captured image of the entire body on a display device; and
acquire a site selected by a user from the displayed captured image of the entire body as the imaging site.

9. The magnetic resonance imaging apparatus according to claim 1,
wherein the processor is configured to:
acquire a captured image of an entire body of the subject;
acquire a plurality of the imaging sites from the acquired captured image of the entire body; and
set the first phase encoding number for each of the acquired plurality of imaging sites.

10. The magnetic resonance imaging apparatus according to claim 1,
wherein the processor is configured to set the first phase encoding number according to resolution set for each imaging site.

11. The magnetic resonance imaging apparatus according to claim 1,
wherein the processor is configured to set the first phase encoding number according to magnetic field distortion set for each imaging site.

12. The magnetic resonance imaging apparatus according to claim 1,
wherein the processor is configured to:
acquire a period of body motion of the acquired imaging site; and
set the first phase encoding number such that acquisition of the first nuclear magnetic resonance signal is completed within the acquired period.

13. A control method of a magnetic resonance imaging apparatus including a static magnetic field generating device that generates a static magnetic field, a transmission device that irradiates a subject placed in a static magnetic field space with a high-frequency magnetic field pulse, a reception device that receives a nuclear magnetic resonance signal generated from the subject by the irradiation of the high-frequency magnetic field pulse, a gradient magnetic field generating device that generates a gradient magnetic field in the static magnetic field space, and a compensation magnetic field generating device that corrects inhomogeneity of the static magnetic field, the control method comprising:
acquiring an imaging site of the subject;
setting a first phase encoding number corresponding to the acquired imaging site;
controlling operations of the transmission device, the reception device, and the gradient magnetic field generating device to acquire a first nuclear magnetic resonance signal with the first phase encoding number;
controlling the operations of the transmission device, the reception device, and the gradient magnetic field generating device and controlling the compensation magnetic field generating device based on the first nuclear magnetic resonance signal to acquire a second nuclear magnetic resonance signal with a second phase encoding number greater than the first phase encoding number; and
reconstructing an image of the subject based on the second nuclear magnetic resonance signal.
